(19) United States
(12) Patent Application Publication
(10) Pub. No.: US 2025/0293094 A1
(43) Pub. Date: Sep. 18, 2025

(54) METHOD FOR MANUFACTURING SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: TERUAKI KUMAZAWA, Nisshin-shi (JP); MASASHI UECHA, Nisshin-shi (JP); YUJI NAGUMO, Nisshin-shi (JP)

(21) Appl. No.: 19/050,193

(22) Filed: Feb. 11, 2025

(30) Foreign Application Priority Data
Mar. 15, 2024 (JP) 2024-041242

(51) Int. Cl. H01L 21/78; H01L 21/3205; H01L 21/683

(52) U.S. Cl. CPC H01L 21/78; H01L 21/32053; H01L 21/6835

(57) ABSTRACT

In a method for manufacturing a semiconductor device, a support plate is attached to a first surface of a semiconductor substrate having element regions, and a metal film is formed on a second surface of the semiconductor substrate to extend over the element regions. A pressing member is pressed against a surface of the metal film along the boundary between the element regions to divide the metal film along the boundary as well as to form a crack in the semiconductor substrate along the boundary and in a thickness direction of the semiconductor substrate. After the pressing member is pressed against the surface of the metal film, the support plate is detached from the first surface of the semiconductor substrate. A dividing member is pressed against the semiconductor substrate from a side adjacent to the first surface and along the boundary to divide the semiconductor substrate along the boundary.

### CROSS REFERENCE TO RELATED APPLICATION

The present application claims the benefit of priority from Japanese Patent Application No. 2024-041242 filed on Mar. 15, 2024. The entire disclosures of the above application are incorporated herein by reference.

### TECHNICAL FIELD

The present disclosure relates to a method for manufacturing a semiconductor device.

### BACKGROUND

As a method for dividing a semiconductor substrate, a scribing and breaking technique has been known. In the scribing and breaking technique, for example, first, a semiconductor substrate is fixed to a support plate, and a pressing member is pressed against a front surface of the semiconductor substrate fixed to the support plate along a boundary between adjacent element regions, thereby to form a crack inside the semiconductor substrate along the boundary. Next, a metal film is formed on the front surface of the semiconductor substrate so as to extend over the element regions. Then, after the support plate is peeled off, a dividing member is pressed against a rear surface of the semiconductor substrate along the boundary, thereby to divide the semiconductor substrate with the metal film along the boundary.

### SUMMARY

The present disclosure describes a method for manufacturing a semiconductor device using a scribing and breaking technique. According to an aspect of the present disclosure a method includes: attaching a support plate to a first surface of a semiconductor substrate having a plurality of element regions; after the attaching of the support plate, forming a metal film on a second surface of the semiconductor substrate opposite to the first surface so as to extend over the plurality of element regions; pressing a pressing member against a surface of the metal film along a boundary between adjacent element regions to divide the metal film along the boundary as well as to form a crack in the semiconductor substrate along the boundary and in a thickness direction of the semiconductor substrate; after the pressing of the pressing member to form the crack, detaching the support plate from the first surface of the semiconductor substrate; and pressing a dividing member against the semiconductor substrate from a side adjacent to the first surface and along the boundary to divide the semiconductor substrate along the boundary.

### BRIEF DESCRIPTION OF DRAWINGS

Objects, features and advantages of the present disclosure will become more apparent from the following detailed description made with reference to the accompanying drawings, in which like parts are designated by like reference numbers and in which:

FIG. 1 is a plan view of a semiconductor substrate;

FIG. 2 is a diagram illustrating a support plate attaching process;

FIG. 3 is a diagram illustrating a grinding process;

FIG. 4 is a diagram illustrating a silicide forming process;

FIG. 5 is a diagram illustrating the silicide forming process;

FIG. 6 is a diagram illustrating a metal film forming process;

FIG. 7 is a diagram illustrating a crack forming process;

FIG. 8 is a diagram illustrating a dicing tape attaching process;

FIG. 9 is diagram illustrating a support plate detaching process;

FIG. 10 is a diagram illustrating a protective member covering process;

FIG. 11 is a diagram illustrating a dividing process; and

FIG. 12 is a diagram illustrating a dice picking process.

### DETAILED DESCRIPTION

In a known scribing and breaking method, as a related art, a semiconductor substrate is fixed to a support plate, and a pressing member is pressed against a front surface of the semiconductor substrate fixed to the support plate along a boundary between adjacent element regions, thereby to form a crack inside the semiconductor substrate along the boundary. A metal film is then formed on the front surface of the semiconductor substrate so as to extend over the element regions. After the support plate is peeled off, a dividing member is pressed against a rear surface of the semiconductor substrate along the boundary, thereby to divide the semiconductor substrate with the metal film along the boundary.

In this case, since the metal film is formed so as to extend over the element regions, when the support plate is peeled off, the semiconductor substrate is likely to be warped due to the film stress of the metal film. If the semiconductor substrate is warped, it is difficult to press the dividing member against the semiconductor substrate with high accuracy, which may cause chips in individual semiconductor devices.

The present disclosure provides a new scribing and breaking technique for dividing a semiconductor substrate having a metal film formed thereon with high accuracy.

In an embodiment of the present disclosure, a method for manufacturing a semiconductor device includes: attaching a support plate to a first surface of a semiconductor substrate having a plurality of element regions; after the attaching of the support plate, forming a metal film on a second surface of the semiconductor substrate opposite to the first surface to extend over the plurality of element regions; pressing a pressing member against a surface of the metal film along a boundary between the plurality of element regions to divide the metal film along the boundary as well as to form a crack in the semiconductor substrate that extends along the boundary and in a thickness direction of the semiconductor substrate; after the pressing of the pressing member, detaching the support plate from the first surface; and pressing a dividing member against the semiconductor substrate from a side adjacent to the first surface and along the boundary to divide the semiconductor substrate along the boundary.

In the method described above, the metal film is formed on the second surface of the semiconductor substrate in a state where the support plate is attached to the first surface of the semiconductor substrate. Thereafter, by pressing the pressing member against the surface of the metal film, the metal film is divided along the boundary between the element regions and the crack is formed in the semiconductor substrate. Since the metal film is divided before the detaching of the support plate, the film stress applied to the semiconductor substrate is reduced when the support plate is detached from the semiconductor substrate. This reduces the warping of the semiconductor substrate caused by the film stress of the metal film. Therefore, the dividing member can be pressed against the semiconductor substrate along the boundary between the element regions with high accuracy, so the occurrence of chips in the manufactured semiconductor device can be suppressed.

In an embodiment of the present disclosure, the manufacturing method may further include, after the attaching of the support plate and before the forming of the metal film, grinding the second surface of the semiconductor substrate.

In such a configuration, the semiconductor device to be manufactured can be made smaller.

In an embodiment of the present disclosure, in the manufacturing method, the metal film may include a silicide layer formed at an interface with the second surface of the semiconductor substrate.

In such a configuration, the contact resistance between the metal film and the semiconductor substrate can be reduced.

### Embodiments

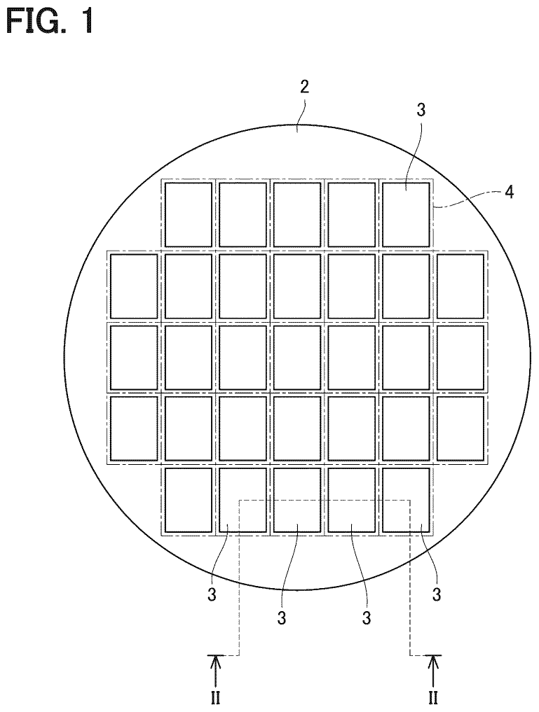

Multiple embodiments of the present disclosure will be described with reference to the drawings. FIG. 1 is a plan view of a semiconductor substrate 2 in which multiple element regions 3 are formed in a matrix. In FIG. 1, each of the element regions 3 is schematically illustrated by a solid line. For convenience of description, lines that are boundaries between adjacent element regions 3 and serves as edge sides of individual element regions (semiconductor devices) after the semiconductor substrate 2 is divided into individual element regions 3 are referred to as planned dividing lines 4. The planned dividing lines 4 are not actually drawn on the semiconductor substrate 2, but are virtual lines. The planned dividing lines 4 may be lines or grooves actually drawn on the semiconductor substrate 2 so as to be visible. In each of the element regions 3, a semiconductor element having a function of, such as a transistor or a diode, is formed.

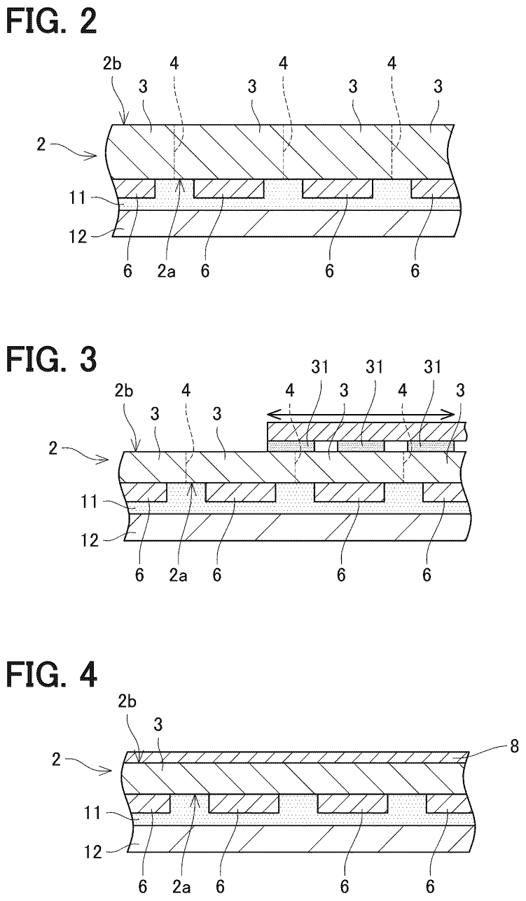

The semiconductor substrate 2 is made of silicon carbide (SiC). The semiconductor substrate 2 may be made of another semiconductor material such as silicon (Si) or gallium nitride (GaN). As shown in FIG. 2 and the like, the semiconductor substrate 2 has a first surface 2a and a second surface 2b located opposite to the first surface 2a in a thickness direction of the semiconductor substrate 2. On the first surface 2a of the semiconductor substrate 2, main structures 6 of the semiconductor element (i.e., structures for realizing the functions of the semiconductor device), such as trenches and gate electrodes, are formed.

In an embodiment, a method for manufacturing the semiconductor device includes a support plate attaching process, a grinding process, a metal film forming process, a crack forming process, a dicing tape attaching process, a support plate detaching process, a protective member covering process, and a dividing process.

### Support Plate Attaching Process

In a support plate attaching process, as shown in FIG. 2, a support plate 12 is attached to the first surface 2a of the semiconductor substrate 2. The support plate 12 is attached to the first surface 2a through an adhesive 11. The support plate 12 is made of, for example, glass. The adhesive 11 is, for example, a silicon-based adhesive. The adhesive 11 has a function of protecting the main structures 6 formed on the first surface 2a of the semiconductor substrate 2, in addition to a function of bonding the semiconductor substrate 2 to the support plate 12. In this case, therefore, the adhesive 11 is applied such that a thickness of the adhesive 11 is greater than a thickness of the main structures 6.

### Grinding Process

Next, as shown in FIG. 3, the second surface 2b of the semiconductor substrate 2 is ground by a grinding wheel 31. As a result, the semiconductor substrate 2 is thinned. The thicknesses of the semiconductor substrate 2 before and after the grinding are not particularly limited, but may be, for example, about 350 nm and about 100 nm, respectively.

### Silicide Layer Forming Process

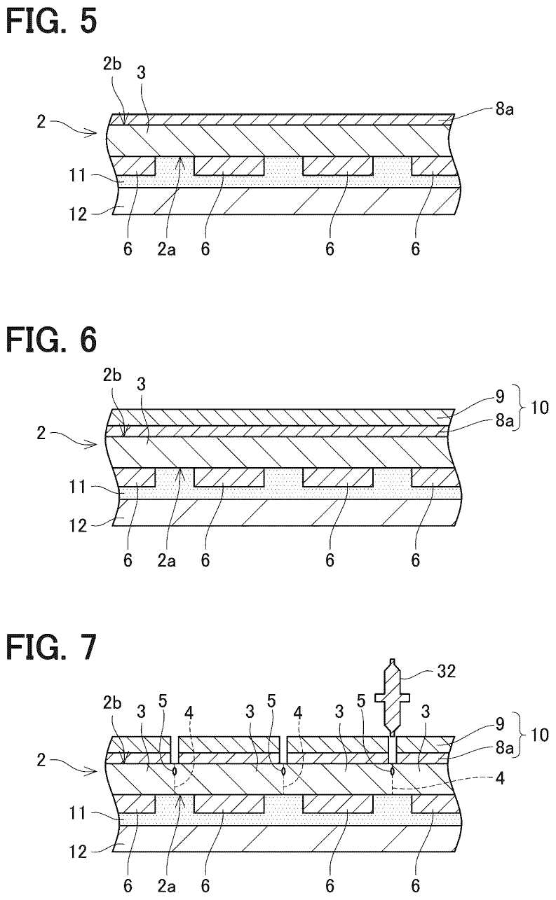

Next, a silicide layer forming process shown in FIGS. 4 and 5 is performed. In the silicide layer forming process, first, a nickel layer 8 is formed on the second surface 2b of the semiconductor substrate 2, as shown in FIG. 4. The nickel layer 8 is formed so as to cover substantially entirely the second surface 2b. That is, the nickel layer 8 is formed on the second surface 2b so as to extend over, i.e., to span the multiple element regions 3. Next, the semiconductor substrate 2 is subjected to a heat treatment. This causes nickel in the nickel layer 8 to react with silicon in the semiconductor substrate 2. As a result, as shown in FIG. 5, a silicide layer 8a in which the nickel and the silicon are alloyed is formed in a range where the nickel layer 8 and the semiconductor substrate 2 are in contact with each other.

### Metal Film Forming Process

Next, a metal film forming process shown in FIG. 7 is performed. In the metal film forming process, a multilayer film 9 in which, for example, titanium, nickel, and gold are laminated is formed on the surface of the silicide layer 8a. The multilayer film 9 is formed so as to cover substantially entirely the silicide layer 8a. That is, the multilayer film 9 is formed on the silicide layer 8a so as to extend over the multiple element regions 3 as spanning the multiple element regions 3. Hereinafter, the silicide layer 8a and the multilayer film 9 will be collectively referred to as a metal film 10. The metal film 10 functions as an electrode of the semiconductor device after completed.

### Crack Forming Process

Next, a crack forming process shown in FIG. 7 is performed. In the crack forming process, a scribing wheel 32 is pressed against the semiconductor substrate 2 attached to the support plate 12, from a side adjacent to the second surface 2b. In other words, in this process, the scribing wheel 32 is pressed against the surface of the metal film 10. As a result, the metal film 10 is divided along the planned dividing lines 4 and a scribe line including a crack 5 is formed inside the semiconductor substrate 2. The scribing wheel 32 is a disk-shaped (annular-shaped) member, and is supported to be rotatable by a support device (not shown). In this case, the scribing wheel 32 is moved (scanned) along the planned dividing lines 4 while being pressed against the surface of the metal film 10. When moving along the planned dividing lines 4, the scribing wheel 32 rolls on the surface of the metal film 10 without slipping, like a tire rolling on a road surface. The scribing wheel 32 has a sharp peripheral edge, but is simply pressed against the surface of the metal film 10. In this process, the scribing wheel 32 is pressed against the surface of the metal film 10 with a load capable of dividing the metal film 10 and forming the crack 5 in the semiconductor substrate 2. When the surface of the metal film 10 is pressed by the scribing wheel 32, a compressive stress is generated inside the semiconductor substrate 2 in the surface layer region of the second surface 2b. While the scribe line (i.e., a groove) is formed at the position pressed by the scribing wheel 32, a tensile stress is generated inside the semiconductor substrate 2 immediately below the region where the compressive stress is generated. The tensile stress occurs at the position immediately below the region where the compressive stress occurs, to be along the second surface 2b of the semiconductor substrate 2 and in a direction away from the planned dividing line 4. This tensile stress causes the crack 5 to be formed inside the semiconductor substrate 2, extending along the planned dividing line 4 and in the thickness direction of the semiconductor substrate 2. In this case, the scribing wheel 32 is moved along the planned dividing line 4 while being pressed against the surface of the metal film 10, so that the metal film 10 is divided along the boundary between the adjacent element regions 3 as well as the crack 5 is formed to extend along the boundary and in the thickness direction. The semiconductor substrate 2 is in a state of being fixed by the support plate 12 made of a relatively hard material. Therefore, when the scribing wheel 32 is pressed against the semiconductor substrate 2, the metal film 10 can be divided and the crack 5 is formed with a relatively small load. The scribing wheel 32 corresponds to an example of a “pressing member”.

### Dicing Tape Attaching Process

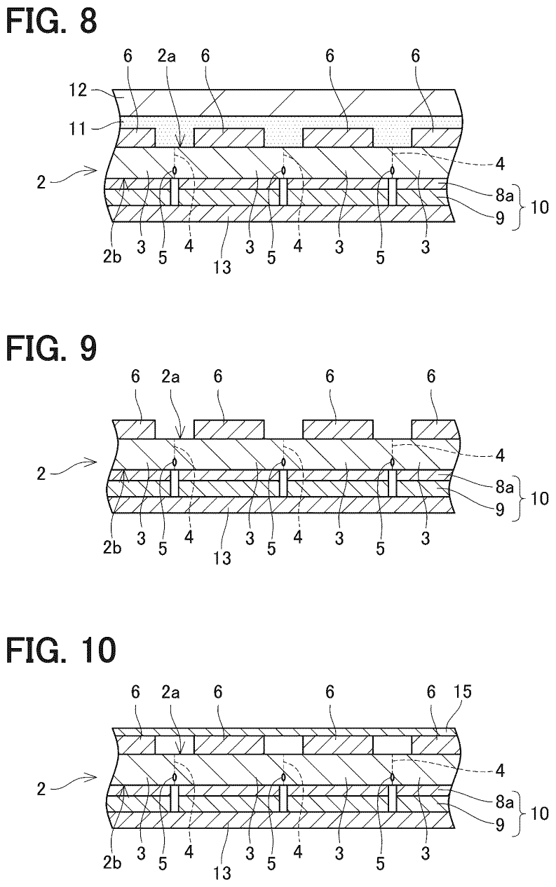

Next, a dicing tape attaching process shown in FIG. 8 is performed. In the dicing tape attaching process, a dicing tape 13 is attached to the surface of the metal film 10. The dicing tape 13 is attached so as to cover substantially entirely the metal film 10. The dicing tape 13 is fixed to a dicing frame (not shown). It should be noted that, in FIG. 8 and the subsequent figures, the semiconductor substrate 2 is depicted with the first surface 2a facing up.

### Support Plate Detaching Process

Next, a support plate detaching process shown in FIG. 9 is performed. In the support plate detaching process, the support plate 12 and the adhesive 11 are detached from the first surface 2a of the semiconductor substrate 2. In this case, for example, the support plate 12 is peeled off from the first surface 2a together with the adhesive 11 by dissolving the adhesive 11 with a solvent. As a result, the semiconductor substrate 2 is in a state of being supported by the dicing tape 13.

### Protective Member Covering Process

Next, a protective member covering process shown in FIG. 10 is performed. In the protective member covering process, a protective member 15 is attached so as to extend over the surfaces of the main structures 6 on the element regions 3 of the semiconductor substrate 2, thereby to cover the first surface 2a of the semiconductor substrate 2 with the protective member 15. The material of the protective member 15 is not particularly limited, and may be, for example, a resin or the like. By covering with the protective member 15, the first surface 2a of the semiconductor substrate 2 is protected in a dividing process or the like performed later.

### Dividing Process

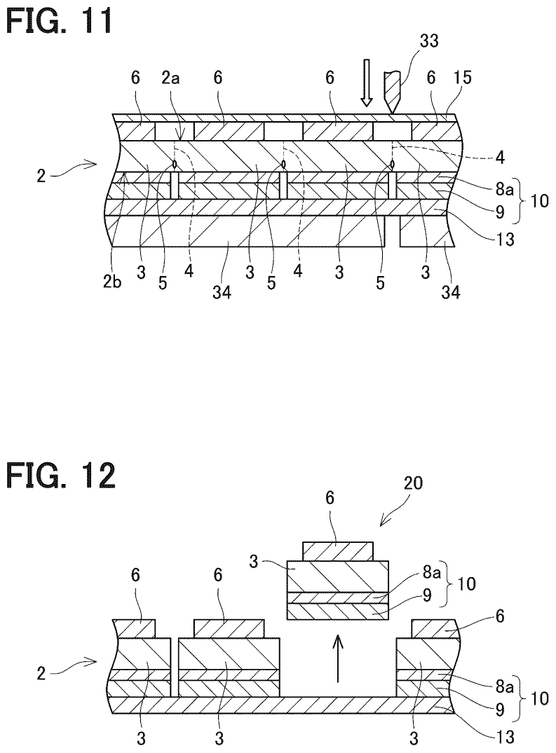

Next, a dividing process shown in FIG. 11 is performed. In the dividing process, a breaking plate 33 is pressed along the planned dividing line 4 (i.e., the crack 5 formed in the crack forming process), to divide the semiconductor substrate 2 along the planned dividing line 4 (i.e., along the boundary of the element regions 3). First, the semiconductor substrate 2 is placed on two support bases 34. The two support bases 34 are spaced apart from each other so as to have a gap therebetween. When the semiconductor substrate 2 is placed on the support bases 34, the semiconductor substrate 2 is placed so that the gap between the two support bases 34 is located below the position where the semiconductor substrate 2 is to be divided (i.e., the position where the breaking plate 33 is to be pressed). Thereafter, the breaking plate 33 is pressed against the first surface 2a of the semiconductor substrate 2 across the protective member 15. The breaking plate 33 is a plate-like member. A lower end of the breaking plate 33 (i.e., an end edge pressed against the first surface 2a) has a ridgeline shape (a sharp edge shape), but is only pressed against the semiconductor substrate 2 without cutting the semiconductor substrate 2.

The support bases 34 are not present below the breaking plate 33, but the gap between the two support bases 34 is located. Therefore, when the breaking plate 33 is pressed against the first surface 2a, the semiconductor substrate 2 is bent so as to enter the gap between the two support bases 34. In this case, the crack 5 has been formed in the semiconductor substrate 2 in the region adjacent to the second surface 2b. Therefore, when the breaking plate 33 is pressed against the semiconductor substrate 2 from the side adjacent to the first surface 2a, the semiconductor substrate 2 is bent about the pressed portion (line). At this time, on the side adjacent to the second surface 2b, a force is applied to the crack 5 in a direction in which the crack 5 is spread and the two element regions 3 adjacent to the crack 5 are separated. As described above, the tensile stress is applied to the periphery of the crack 5. Therefore, when the breaking plate 33 is pressed against the first surface 2a, the crack 5 extends in the thickness direction of the semiconductor substrate 2, and the semiconductor substrate 2 is divided along the planned dividing line 4. Instead of the two support bases 34, for example, the entire second surface 2b of the semiconductor substrate 2 may be supported by one elastic support plate (or one or more support bases via one elastic support plate). In such a case, although the elastic support plate is present below the breaking plate 33, when the semiconductor substrate 2 is bent, the elastic support plate is deformed according to the bending of the semiconductor substrate 2. Therefore, when the breaking plate 33 is pressed against the first surface 2a, a force is applied to the crack 5 in a direction in which the two element regions 3 adjacent to the dividing position are separated from each other, as in the case where the semiconductor substrate 2 is supported by the two support bases 34 (i.e., the case where the support base 34 is not present below the breaking plate 33). The breaking plate 33 corresponds to an example of a “dividing member”.

In the dividing process, the process of pressing the breaking plate 33 against the first surface 2a is repeatedly performed along each of the planned dividing lines 4. As a result, the semiconductor substrate 2 can be divided along the boundaries between the element regions 3. The metal film 10 has already been divided along the boundaries in the crack forming process described above. Therefore, by performing the dividing process, the semiconductor substrate 2 and the metal film 10 can be divided along the boundaries between the element regions 3. Thereafter, as shown in FIG. 12, the divided element regions 3 with the metal films 10 are separated from the dicing tape 13. When the divided element regions 3 with the metal films 10 are separated from the dicing tape 13, the dicing tape 13 is expanded so that the divided element regions 3 with the metal films 10 are spaced apart from each other. In this way, the semiconductor devices 20 each having the metal film 10 (electrode) formed on the surface are completed.

As described above, in the present embodiment, the metal film 10 is formed on the second surface 2b of the semiconductor substrate 2 in a state where the support plate 12 is attached to the first surface 2a of the semiconductor substrate 2. Thereafter, the scribing wheel 32 is pressed against the surface of the metal film 10, so that the metal film 10 is divided along the boundary of the element regions 3 and the crack 5 is formed inside the semiconductor substrate 2. The metal film 10 is divided in the process of forming the crack 5. Therefore, the film stress applied to the semiconductor substrate 2 when the support plate 12 is detached from the semiconductor substrate 2 is low. Therefore, warping of the semiconductor substrate 2 caused by the film stress of the metal film 10 is reduced. As such, the breaking plate 33 can be pressed against the semiconductor substrate 2 along the boundary of the element regions 3 with high accuracy, and hence the occurrence of chips in the manufactured semiconductor devices 20 can be suppressed.

In the present embodiment, after the support plate 12 is attached to the first surface 2a of the semiconductor substrate 2, the second surface 2b of the semiconductor substrate 2 is ground by the grinding wheel 31. Therefore, the semiconductor device 20 to be manufactured can be made smaller.

In the present embodiment, the metal film 10 includes the silicide layer 8a formed at the interface with the second surface 2b of semiconductor substrate 2. Therefore, when the metal film 10 functions as an electrode, the contact resistance between the metal film 10 and the semiconductor substrate 2 can be reduced.

In the embodiment described above, the grinding process, the silicide layer forming process, the dicing tape attaching process, or the protective member covering process may not be performed.

Although the embodiments have been described in detail above, these are merely examples and do not limit the scope of claims. The techniques described in the claims include various modifications and modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve objectives at the same time, and achieving one of the objectives itself has technical usefulness.

What is claimed is:

1. A method for manufacturing a semiconductor device, the method comprising:
attaching a support plate to a first surface of a semiconductor substrate having a plurality of element regions;
after the attaching of the support plate, forming a metal film on a second surface of the semiconductor substrate opposite to the first surface to extend over the plurality of element regions;
pressing a pressing member against a surface of the metal film along a boundary between the plurality of element regions to divide the metal film along the boundary as well as to form a crack in the semiconductor substrate along the boundary and in a thickness direction of the semiconductor substrate;
after the pressing of the pressing member, detaching the support plate from the first surface of the semiconductor substrate; and
pressing a dividing member against the semiconductor substrate from a side adjacent to the first surface and along the boundary to divide the semiconductor substrate along the boundary.

2. The method according to claim 1, further comprising:
after the attaching of the support plate and before the forming of the metal film, grinding the second surface of the semiconductor substrate.

3. The method according to claim 1, wherein
the metal film includes a silicide layer formed at an interface with the second surface of the semiconductor substrate.
